(19) United States
(12) Patent Application Publication
(10) Pub. No.: US 2016/0091578 A1
(43) Pub. Date: Mar. 31, 2016

(54) FULL-BAND POWER AMPLIFIER WITH A SWITCHED PARTIAL-BAND BOOSTER STAGE DEVICES AND RELATED SYSTEMS AND METHODS

(71) Applicant: Agilent Technologies, Inc., Santa Clara, CA (US)

(72) Inventor: Michael Schoessow, Santa Clara, CA (US)

(21) Appl. No.: 14/501,627

(22) Filed: Sep. 30, 2014

(51) Int. Cl. G01R 33/36; G01R 33/48

(52) U.S. Cl. CPC G01R 33/3614; G01R 33/48

(57) ABSTRACT

A radio frequency (RF) source signal is received at a first amplifier and amplified to a first power level over a wide frequency range, which may include frequencies effective for resonantly exciting nuclear magnetic resonance (NMR)-active nuclei. The amplified signal may be transmitted over a first path or a second path, which may be selected via a switch. When the first path is selected, the amplified signal is transmitted over the wide frequency range to a signal output. When the second path is selected, the amplified signal is received at a second amplifier, amplified to a second power level over a low frequency range, and transmitted to the signal output.

### TECHNICAL FIELD

The present invention relates generally to RF power amplification, and in particular to providing a full-band power amplifier with a switched partial-band booster stage. As one example, the full-band power amplifier may be part of a radio frequency (RF) signal transmitter in a nuclear magnetic resonance (NMR) or magnetic resonance imaging (MRI) system.

### BACKGROUND

An NMR apparatus is utilized to obtain useful information from a sample of interest. The sample may be a chemical specimen (e.g., a contained liquid or solid object) or a biological organism (e.g., a human or animal). An NMR apparatus may be configured as an NMR spectrometer that obtains spectral data indicative of molecular structure, position and abundance. An NMR apparatus may also be configured as a (nuclear) magnetic resonance imaging (MRI) apparatus that obtains imaging data indicative of the position and pathology of tissues and organs.

In a typical NMR apparatus, an NMR tube (typically a thin-walled glass tube) containing the sample is loaded into an NMR probe such that the sample is surrounded by one or more radio frequency (RF) coils of the NMR probe. The NMR probe is inserted into a bore that is surrounded by a magnet. The magnet generates a high-strength (typically a 3 to 20 Tesla) static magnetic field, or B₀ field, along the central axis of the magnet bore, or z-axis. NMR-active nuclei of the sample, such as protons (hydrogen nuclei) and carbon-13 nuclei, behave as magnetic dipoles and become aligned with the B₀ field along the z-axis. Passive shims and/or active shim coils may be positioned in the bore and utilized to correct inhomogeneities in the applied B₀ field.

One of the RF coils is utilized as a transmit coil to apply a pulsed magnetic field, or B₁ field, to the sample. The B₁ field is typically orthogonal to the B₀ field and oscillates in the RF range (i.e., on the order of 10 MHz to 1 GHz). The transmit coil is tuned to resonantly excite the NMR-active nuclei of interest in the sample. The resonance condition is fulfilled when the frequency of the applied B₁ field equals the Larmor frequency of the nucleus of interest. The Larmor frequency, ν, depends on the type of nucleus and the strength of the B₀ field as follows: ν=(γB₀)/2π, where γ is the gyromagnetic ratio of the nucleus and B₀ is the magnitude of the B₀ field. At resonance, the B₁ field efficiently transfers electromagnetic energy to the nucleus and causes a change in energy state. During the delay interval between pulses the excited nucleus emits an RF time-domain signal, known as a free-induction decay (FID), as a result of this perturbation. The FID decays in the interval as the excited nucleus relaxes back to its equilibrium state. The FID is picked up as an NMR measurement signal by the RF coil (the receive coil or pick-up coil, which may be the same coil utilized for excitation or a different coil). Electronics of the NMR system amplify and process the NMR measurement signal as needed to construct an NMR spectrum containing information regarding the irradiated sample. For example, the signal may be converted from the time domain to frequency domain by Fourier transformation. The NMR spectrum typically consists of one or more peaks whose intensities represent the proportions of each frequency component detected.

To resonantly excite the NMR-active nuclei of interest using the transmit coil, the system typically uses an RF source signal requiring both a low-band and high-band amplifier, with the power requirement being substantially higher for one RF power amplifier than for the other.

The typical RF power amplifier requirements in NMR and MRI systems are for at least one high-band amplifier and for at least one low-band amplifier. Some systems require two high-band amplifiers and it is relatively common for systems to require two to three low-band amplifiers. MRI systems often employ numerous low-band amplifiers. The high-band frequency requirements are typically for narrow operating bandwidths (less than 5% of the center frequency) and it is often desirable to be able to operate at 10-20 different center frequencies across the range of 300 to 1000 MHz. Typical RF output power requirements are 20 to 100 watts, depending on the system architecture and probe (antenna/load) design. The low-band frequency requirements are also for narrow operating bandwidths but frequency coverage must span a wide and practically continuous range from as low as 2 MHz to as high as 400 MHz, in some applications, although ranges such as 20-250 MHz are much more common. RF output power requirements range from 150 watts to multiple kilowatts, depending on system architecture and probe design. It should be understood that, in general, because the cost of the devices correlate to the RF output power requirements, low-band amplifiers are substantially more costly than high-band amplifiers. In systems having more than one RF power amplifier, a very common requirement is simultaneous operation of multiple RF power amplifiers. Also, virtually all NMR or MRI applications require the operation of at least one high-band amplifier.

Typically, these requirements are satisfied via two different approaches. The first, and most common, approach is to employ a selection of discrete high-band and low-band amplifiers, as necessary to cover all anticipated applications. For example, if the anticipated modes of operation included High/High (H/H; simultaneous operation of two high-band amplifiers), High/Low (H/L), and High/Low/Low (H/L/L), then the system would include four RF power amplifiers, two high-band and two low-band amplifiers. For lower-frequency, lower-power systems, it is typical to employ a second approach, that of wide-band RF power amplifiers that span both the high-band and low-band frequency and also their corresponding power requirements. For example, if the system high-band amplifier requirement were for 50 watts at 300-400 MHz and the low-band requirement were for 150 watts across 20-200 MHz, then a single amplifier design that generated 150 watts from 20-200 MHz, with the power falling off to 50 watts by 400 MHz, would satisfy both the high-band and low-band requirements. Such a scheme has the advantage of facilitating H/H as well as H/L modes of operation with only two RF power amplifiers, since each RF power amplifier can provide high or low frequency and power coverage. With three such RF power amplifiers, H/H, H/L, and H/L/L modes could all be supported. In this manner, one less amplifier than the first approach may be possible. Since RF power amplifiers are one of the most expensive single components in a system, requiring one less is a significant advantage.

While the second approach may be more cost effective than the first approach because of fewer amplifiers, the second approach is not presently practical for systems operating at higher frequencies or requiring higher low-band power levels. This is due to performance limitations in the available semiconductor devices employed in the power output stages of the amplifiers. As an example, typical semiconductor RF power devices suitable for amplifier output powers exceeding approximately 100 watts are limited to frequency ranges such as, for example, DC to 500 MHz, or 400 to 1000 MHz, etc., with no available devices capable of both high power (such as 300-1000 watts) and DC-1000 MHz frequency coverage. The combining of multiple smaller devices to achieve the desired level of wide-band power is possible but problematic in terms of manufacturing costs due to the requirements for precise phase matching between devices as well as more complex matching networks and additional bias circuits. Therefore there is presently a need to provide for a RF power amplifier configuration that is both cost effective for the range of required frequencies in a NMR and MRI system, and that also provides for a smaller physical size requirement.

### SUMMARY

To address the foregoing problems, in whole or in part, and/or other problems that may have been observed by persons skilled in the art, the present disclosure provides methods, processes, systems, apparatus, instruments, and/or devices, as described by way of example in implementations set forth below.

According to one embodiment, a radio frequency (RF) power amplifier for a nuclear magnetic resonance (NMR) apparatus may include a first stage amplifier configured to receive an RF source signal. The first stage amplifier may be configured to amplify the RF source signal to a first power level and over a wide frequency range comprising frequencies effective for resonantly exciting high-frequency NMR-active nuclei and low-frequency NMR-active nuclei. The RF power amplifier may include a first switch comprising a switch input and a switch output. The RF power amplifier may further include a second switch comprising a first switch input, a second switch input, and a switch output. The RF power amplifier may also include a wide-band matching circuit in electrical communication between the first stage amplifier and the switch input of the first switch and the first switch input of the second switch. The wide-band matching circuit may be configured to output the amplified RF source signal as a first RF output signal at the wide frequency range when the second switch is controlled to output the first RF output signal received at the first switch input of the second switch. The RF power amplifier may further include a second stage amplifier in electrical communication between the switch output of the first switch and the second switch input of the second switch. The second stage amplifier may be configured to receive the amplified RF source and configured to output the amplified RF source signal as a second RF output signal at a second power level higher than the first power level, and at a low frequency range comprising frequencies effective for resonantly exciting low-frequency NMR-active nuclei when the second switch is controlled to output the second RF output signal received at the second switch input of the second switch.

According to another embodiment, the RF power amplifier includes a wide frequency range from 5 MHz to 1000 MHz.

According to another embodiment, the RF power amplifier includes a wide frequency range over frequencies effective to resonantly excite hydrogen and fluorine nuclei, deuterium, carbon, nitrogen, potassium, and phosphorous nuclei.

According to another embodiment, the RF power amplifier includes a low-band interstage matching circuit with an input impedance and an output impedance. The low-band interstage matching circuit may be configured to impedance match between an output impedance of the switch output of the first switch and an input impedance of the second stage amplifier; and a low-band output matching circuit with an input impedance and an output impedance, the low-band output matching circuit may be configured to impedance match between an output impedance of the second stage amplifier and an input impedance of the second switch input of the second switch.

According to another embodiment, the RF power amplifier includes a control unit to selectively control the first switch and the second switch.

According to another embodiment, the output impedance of the wide-band matching circuit substantially equals 50 ohms.

According to another embodiment, a radio frequency (RF) power amplifier for a nuclear magnetic resonance (NMR) apparatus includes a first stage amplifier configured to receive an RF source signal and configured to amplify the RF source signal to a first power level and over a wide frequency range comprising frequencies effective for resonantly exciting high-frequency NMR-active nuclei and low-frequency NMR-active nuclei. The RF power amplifier includes a first switch comprising a switch input, a first switch output, and a second switch output. The RF power amplifier also includes a second switch comprising a first switch input, a second switch input, and a switch output. The RF power amplifier also includes a wide-band matching circuit in electrical communication between the first stage amplifier and the switch input of the first switch, and configured to output the amplified RF source signal as a first RF output signal at the wide frequency range. The RF power amplifier also includes a second stage amplifier in electrical communication between the second switch output of the first switch and the second switch input of the second switch, and configured to output the amplified RF source signal as a second RF output signal at a second power level higher than the first power level, and at a low frequency range comprising frequencies effective for resonantly exciting low-frequency NMR-active nuclei when the second switch is controlled to output the second RF output signal received at the second switch input of the second switch.

According to another embodiment, the wide frequency range spans a bandwidth from 5 MHz to 1000 MHz.

According to another embodiment, the wide frequency range comprises frequencies effective to resonantly excite hydrogen and fluorine nuclei, deuterium, carbon, nitrogen, potassium, and phosphorous nuclei.

According to another embodiment, the RF power amplifier includes a low-band interstage matching circuit with an input impedance and an output impedance, wherein the low-band interstage matching circuit is configured to impedance match between an output impedance of the second switch output and an input impedance of the second stage amplifier. The RF power amplifier also includes a low-band output matching circuit with an input impedance and an output impedance, wherein the low-band output matching circuit is configured to impedance match between an output impedance the second stage amplifier and an input impedance of the second switch input of the second switch.

According to another embodiment, a control unit may be configured to selectively control the first switch and the second switch.

According to another embodiment, a method of receiving at a first stage amplifier an RF source signal. The method also includes amplifying the RF source signal by the first stage amplifier to a first power level and over a wide frequency range comprising frequencies effective for resonantly exciting high-frequency NMR-active nuclei and low-frequency NMR-active nuclei. The method also includes receiving the amplified RF source signal at a first switch comprising a switch input and a switch output. The method also includes receiving the amplified RF source signal at a second switch comprising a first switch input, a second switch input, and a switch output. The method also includes matching the impedance using a wide-band matching circuit in electrical communication between the first stage amplifier and the switch input of the first switch and the first switch input of the second switch. The method also includes outputting the amplified RF source signal as a first RF output signal at the wide frequency range when the second switch is controlled to output the first RF output signal received at the first switch input of the second switch. The method also includes matching the impedance using a second stage amplifier in electrical communication between the switch output of the first switch and the second switch input of the second switch. The method also includes receiving the amplified RF source at the second stage amplifier for amplification. The method also includes outputting the amplified RF source signal as a second RF output signal at a second power level higher than the first power level, and at a low frequency range comprising frequencies effective for resonantly exciting low-frequency NMR-active nuclei when the second switch is controlled to output the second RF output signal received at the second switch input of the second switch.

According to another embodiment, amplifying the RF source signal to the first power level and over the wide frequency range comprises amplifying the RF source signal over frequencies ranging from 5 MHz to 1000 MHz.

According to another embodiment, amplifying the RF source signal to the first power level and over the wide frequency range comprises amplifying the RF source signal over frequencies effective for resonantly exciting hydrogen and fluorine nuclei, deuterium, carbon, nitrogen, and phosphorous nuclei.

According to another embodiment, providing a low-band interstage matching circuit with an input impedance and an output impedance for impedance matching between an output impedance of the switch output of the first switch and an input impedance of the second stage amplifier; and providing a low-band output matching circuit with an input impedance and an output impedance for impedance matching between an output impedance of the second stage amplifier and an input impedance of the second switch input of the second switch.

According to another embodiment, providing a control unit for selectively controlling the first switch and the second switch.

According to another embodiment, using a wide-band matching circuit further comprises using a wide-band matching circuit with an output impedance substantially equal to 50 ohms.

According to another embodiment, a method of receiving at a first stage amplifier an RF source signal for amplification. The method also includes amplifying the RF source signal by the first stage amplifier to a first power level and over a wide frequency range comprising frequencies effective for resonantly exciting high-frequency NMR-active nuclei and low-frequency NMR-active nuclei. The method also includes matching the impedance using a wide-band matching circuit in electrical communication between the first stage amplifier and a first switch, the first switch comprising a switch input, a first switch output, and a second switch output. The method also includes receiving the amplified RF source signal at a second switch comprising a first switch input, a second switch input, and a switch output. The method also includes amplifying the amplified RF source signal using a second stage amplifier in electrical communication between the second switch output of the first switch and the second switch input of the second switch. The method also includes outputting the amplified RF source signal as a second RF output signal by the second stage amplifier at a second power level higher than the first power level, and at a low frequency range comprising frequencies effective for resonantly exciting low-frequency NMR-active nuclei when the second switch is controlled to output the second RF output signal received at the second switch input of the second switch.

According to another embodiment, amplifying the RF source signal to the first power level and over the wide frequency range comprises amplifying the RF source signal over frequencies ranging from 5 MHz to 1000 MHz.

According to another embodiment, amplifying the RF source signal to the first power level and over the wide frequency range comprises amplifying the RF source signal over frequencies effective for resonantly exciting hydrogen and fluorine nuclei, deuterium, carbon, nitrogen, potassium, and phosphorous nuclei.

According to another embodiment, providing a low-band interstage matching circuit with an input impedance and an output impedance for impedance matching between an output impedance of the second switch output and input impedance of the second stage amplifier. Also providing a low-band output matching circuit with an input impedance and an output impedance for impedance matching between an output impedance the second stage amplifier and an input impedance of the second switch input of the second switch.

According to another embodiment, providing a control unit configured for selectively controlling switching between the first signal path and the second signal path.

According to another embodiment, using a wide-band matching circuit further comprises using a wide-band matching circuit with an output impedance substantially equal to 50 ohms.

According to another embodiment, RF power amplifier for a nuclear magnetic resonance (NMR) apparatus, the RF power amplifier includes a first stage amplifier configured to receive an RF source signal and configured to amplify the RF source signal to a first power level and over a wide frequency range comprising frequencies effective for resonantly exciting high-frequency, NMR-active nuclei and low-frequency, NMR-active nuclei in the NMR apparatus. The RF power amplifier also includes a switch comprising a first switch input, a second switch input, and a switch output for operative electrical communication with the NMR apparatus, the switch being configured to selectively output at the switch output an input to the first switch input or an input to the second switch input. The RF power amplifier also includes a high-pass filter in electrical communication between an output of the first stage amplifier and the first switch input, the high-pass filter being configured to receive the amplified RF source and configured to output the amplified RF source signal as a first RF output signal at a high frequency range comprising frequencies effective for resonantly exciting high-frequency, NMR-active nuclei when the switch is controlled to output the input to the first switch input. The RF power amplifier also includes a second stage amplifier in electrical communication between the first stage amplifier and the second switch input, the second stage amplifier being configured to receive the amplified RF source and configured to output the amplified RF source signal as a second RF output signal at a second power level higher than the first power level, and at a low frequency range comprising frequencies effective for resonantly exciting low-frequency NMR-active nuclei when the switch is controlled to output the input to the second switch input.

According to another embodiment, the wide frequency range spans a bandwidth of a range from 5 MHz to 1000 MHz.

According to another embodiment, the high frequency range comprises frequencies effective to resonantly excite hydrogen and fluorine nuclei, deuterium, carbon, nitrogen, potassium, and phosphorous nuclei.

According to another embodiment, a high-band output matching circuit for impedance matching between the high-pass filter and the switch.

According to another embodiment, a low-band interstage matching circuit for impedance matching between the first stage amplifier and the second stage amplifier. Also, a low-band output matching circuit for impedance matching between the second stage amplifier and the switch.

According to another embodiment, a control unit may be configured to selectively control switching between the first signal path and the second signal path.

According to another embodiment, a radio frequency (RF) power amplifier for amplifying a radio frequency (RF) source signal includes a first stage amplifier. The first stage amplifier is configured to receive an RF source signal. The first stage amplifier is also configured to amplify the RF source signal at the first stage amplifier to a first power level and over a wide frequency range comprising frequencies effective for resonantly exciting high-frequency nuclear magnetic resonance (NMR)-active nuclei and low-frequency NMR-active nuclei. The RF power amplifier also includes a first signal path configured to transmit the amplified RF source signal over the wide frequency range to a RF signal output. The RF power amplifier also includes a second signal path configured to transmit the amplified RF source signal, wherein the second signal path includes a second stage amplifier configured to receive the amplified RF source signal. The second stage amplifier is also configured to amplify the RF source signal a second power level higher than the first power level, and over a low frequency range comprising frequencies effective for resonantly exciting low-frequency NMR-active nuclei. The second stage amplifier is also configured to transmit the amplified RF source signal over the low frequency range to the RF signal output. The RF power amplifier is also configured to selectively switch between transmitting the amplified RF source signal over the first signal path and the second signal path.

According to another embodiment, the RF power amplifier also includes a switch assembly, the switch assembly includes a first switch and a second switch. The RF power amplifier also includes a wide-band matching circuit configured to match the impedance between the first stage amplifier and the switch assembly. The first signal path also includes the second switch configured to transmit the amplified RF source signal to the RF signal output. The second signal path also includes a low-band interstage matching circuit configured to match the impedance between the first switch and the second stage amplifier. The second signal path also includes a low-band output matching circuit configured to match the impedance between the second stage amplifier and the second switch.

According to another embodiment, the RF power amplifier also includes a switch assembly, the switch assembly includes a first switch and a second switch. The RF power amplifier also includes a wide-band matching circuit configured to match the impedance between the first stage amplifier and the switch assembly. The first signal path also includes the first switch and the second switch configured to transmit the amplified RF source signal to the RF signal output. The second signal path also includes the first switch configured to transmit the amplified RF source signal. The second signal path also includes a low-band interstage matching circuit configured to match the impedance between the first switch and the second stage amplifier. The second signal path also includes a low-band output matching circuit configured to match the impedance between the second stage amplifier and the second switch. The second signal path also includes the second switch configured to transmit the amplified RF source signal over the low frequency range to the RF signal output.

According to another embodiment, the control unit is provided for controlling the first switch and the second switch. In some embodiments, the control unit comprises a field-programmable gate array (FPGA).

According to another embodiment, the first stage amplifier is configured to amplify the RF source signal to a range of 20 watts to 200 watts.

According to another embodiment, second stage amplifier is configured to amplify the amplified RF source signal to a range of 250 watts to 400 watts.

According to another embodiment, a transmission pathway between the inputs of the first switch and the second switch is less than one-tenth ( 1/10) wavelength at the highest operating frequency of the amplified RF source signal.

According to another embodiment, a method for amplifying a radio frequency (RF) source signal includes receiving the RF source signal at a first stage amplifier. The method also includes amplifying the RF source signal at the first stage amplifier to a first power level and over a wide frequency range comprising frequencies effective for resonantly exciting high-frequency nuclear magnetic resonance (NMR)-active nuclei and low-frequency NMR-active nuclei. The method also includes switching selectively between transmitting the amplified RF source signal over a first signal path and a second signal path. The method also includes transmitting the amplified RF source signal over the first signal path including transmitting the amplified RF source signal over the wide frequency range to a RF signal output. The method also includes transmitting the amplified RF source signal over the second signal path including receiving the amplified RF source signal at a second stage amplifier. The method also includes amplifying the RF source signal at the second stage amplifier to a second power level higher than the first power level, and over a low frequency range comprising frequencies effective for resonantly exciting low-frequency NMR-active nuclei. The method also includes transmitting the amplified RF source signal over the low frequency range to the RF signal output.

According to another embodiment, the method further includes matching the impedance between the first stage amplifier and a switch assembly using a wide-band matching circuit, the switch assembly comprising a first switch and a second switch. The method also includes transmitting the amplified RF source signal over the first signal path further including transmitting the amplified RF source signal to the RF signal output via the second switch. The method also includes transmitting the amplified RF source signal over the second signal path further including matching the impedance between the first switch and the second stage amplifier using a low-band interstage matching circuit. The method also includes matching the impedance between the second stage amplifier and the second switch using a low-band output matching circuit.

According to another embodiment, the method further includes matching the impedance between the first stage amplifier and a switch assembly using a wide-band matching circuit, the switch assembly includes a first switch and a second switch. The method includes transmitting the amplified RF source signal over the first signal path further includes transmitting the amplified RF source signal to the RF signal output via the first switch and the second switch. The method also includes transmitting the amplified RF source signal over the second signal path further comprises. The method also includes transmitting the amplified RF source signal via the first switch. The method also includes matching the impedance between the first switch and the second stage amplifier using a low-band interstage matching circuit. The method also includes matching the impedance between the second stage amplifier and the second switch using a low-band output matching circuit. The method also includes transmitting the amplified RF source signal over the low frequency range to the RF signal output via the second switch.

According to another embodiment, the method includes providing a control unit to control switching between the first signal path and the second signal path.

According to another embodiment, the control unit comprises a field-programmable gate array (FPGA).

According to another embodiment, amplifying the RF source signal to the first power level comprises amplifying the RF source signal to a range of 20 watts to 200 watts.

According to another embodiment, amplifying the amplified RF source signal comprises amplifying the amplified RF source signal to a range of 250 watts to 400 watts.

According to another embodiment, transmitting the amplified RF source signal over the second signal path comprises transmitting the amplified RF source signal over a transmission pathway between the inputs of the first switch and the second switch, wherein the transmission pathway between the inputs of the first switch and the second switch is less than one-tenth ( 1/10) wavelength at the highest operating frequency of the amplified RF source signal.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIG. 1 is a schematic view of an example of a nuclear magnetic resonance (NMR) apparatus and associated system according to some embodiments;

FIG. 2 is a block diagram of an example of a full-band power amplifier with a switched partial-band booster stage according to some embodiments;

FIG. 3 is a block diagram of another example of a full-band power amplifier with a switched partial-band booster stage according to some embodiments;

FIG. 4 is a block diagram of another example of a full-band power amplifier with a switched partial-band booster stage according to some embodiments;

FIG. 5 is a flowchart of an example method for full-band power amplification with a switched partial-band booster stage according to some embodiments;

FIG. 6 is a flowchart of another example method for full-band power amplification with a switched partial-band booster stage according to some embodiments;

FIG. 7A is a block diagram of a prior art example for a typical RF power amplifier; and

FIG. 7B is a block diagram of an example of a RF power amplifier according to some embodiments.

### DETAILED DESCRIPTION

As used herein, the term “NMR-active nuclei” refers to nuclei possessing the quantum property of spin and that behave as magnetic dipoles and thus are responsive to radio frequency (RF) irradiation in a manner useful for NMR-related measurements. Terms such as “high resonance frequency nucleus,” “high-frequency nucleus” and “HF nucleus” refer to nuclei having a higher resonance frequency in a magnetic field of a given field strength, relative to other types of nuclei in the same magnetic field. Typical examples of high-frequency nuclei are tritium (³H), hydrogen (or proton, ¹H), and fluorine (e.g., the fluorine isotope ¹⁹F). Terms such as “low resonance frequency nucleus,” “low-frequency nucleus” and “LF nucleus” generally refer to nuclei having a lower resonance frequency than ¹⁹F in a magnetic field of the same given field strength. Many different types of nuclei may be characterized as low-frequency nuclei as appreciated by persons skilled in the art, a few common examples being phosphorous (e.g., the phosphorous isotope ³¹P), carbon (e.g., the carbon isotope ¹³C), deuterium (²H), potassium (³⁹K), and nitrogen (e.g., the nitrogen isotope ¹⁵N).

As used herein, the term “resonance frequency” (or “Larmor frequency”) refers to the resonance frequency of a nucleus that may be electromagnetically coupled with an RF coil. The resonance condition is fulfilled if the frequency of the applied RF energy equals the resonance (or Larmor) frequency ν₀ of the NMR-active nucleus being irradiated, which depends on the type of nucleus and the strength of the B₀ field. The resonance frequency ν₀ may be expressed as ν₀=−γB₀, where γ is the gyromagnetic ratio of the nucleus, as appreciated by persons skilled in the art. At resonance, the B₁ field efficiently transfers electromagnetic energy to the nucleus.

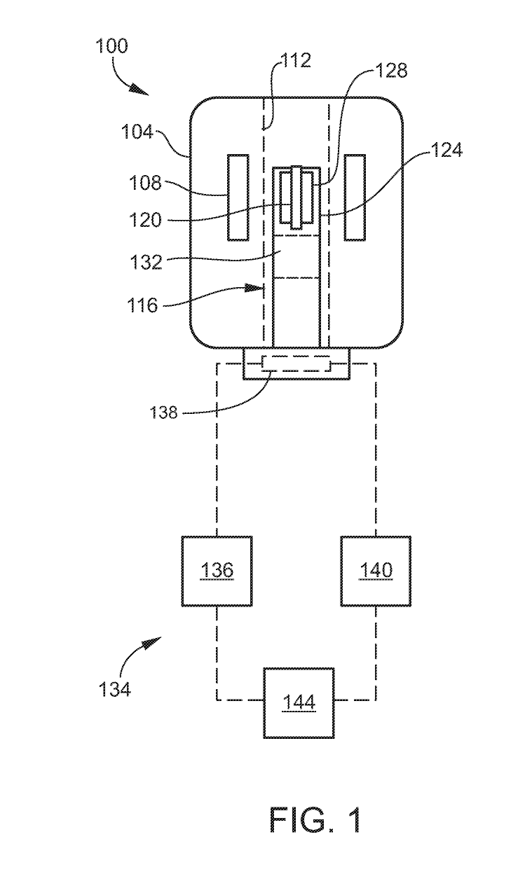

FIG. 1 is a schematic view of an example of a nuclear magnetic resonance (NMR) apparatus and associated system. In the embodiment specifically illustrated, the NMR apparatus is an NMR spectrometer (or spectrometry system) 100 according to some embodiments. Generally, the structure and operation of NMR spectrometers are understood by persons skilled in the art, and thus certain components and features the NMR spectrometer 100 are described briefly to facilitate an understanding of the subject matter taught herein. An NMR apparatus may also be configured as a (nuclear) magnetic resonance imaging (MRI) apparatus that obtains imaging data indicative of the position and pathology of tissues and organs.

The NMR spectrometer 100 may generally include an outer vacuum case (OVC) or housing 104. The OVC 104 may enclose various components, including a magnet 108 for applying a static (and preferably highly homogeneous) magnetic B₀ field in the range of field densities specified for operation. In some embodiments, the magnet 108 is a superconducting magnet (or high temperature superconducting (HTS) magnet) that exhibits superconductivity at low or very low (cryogenic) temperatures. In such embodiments, the NMR spectrometer 100 includes a cryostat, which includes the OVC 104 and an internal cryogenic cooling system. In such embodiments, the OVC 104 is configured for enclosing the magnet 108 and the internal cryogenic cooling system in a gas-tight manner and maintaining the interior of the OVC 104 at a vacuum level to minimize heat transfer. The OVC 104 includes or is coupled to a bore (tube) 112 in which an NMR probe 116 may be inserted or removed. One axial end of the bore 112 may extend to the exterior of the OVC 104 to facilitate loading and removal of the NMR probe 116 (such as from the bottom). The magnet 108 surrounds the bore 112 and thus the NMR probe 116, and thus is typically annular or toroidal such as in the form of an electromagnet or coil. The magnet 108 is typically oriented and configured for producing axial magnetic field lines along the central axis of the bore 112. The bore 112 may be thermally isolated from the cryogenic interior of the OVC 104, whereby the sample under investigation residing in the bore 112 may be maintained at a temperature controlled independently from the interior of the OVC 104. Thus, for example, experiments on the sample may be carried out at room temperature or variable temperature while interior regions of the OVC 104 are maintained at different temperatures such as cryogenic temperatures.

The NMR probe 116 is configured for supporting an NMR tube (sample holder) 120 such that the sample under investigation contained in the NMR tube 120 is positioned properly in the homogeneous magnetic B₀ field. The NMR probe 116 may generally include a probe housing or body 124 containing a radio frequency (RF) coil 128 and NMR probe circuitry (electronics). In some embodiments, the RF coil 128 may schematically represent one or more individual RF coils. That is, separate RF coils may be utilized for transmitting RF excitation signals (thereby applying the above-noted B₁ field) to the sample and for receiving RF signals (NMR measurement signals) from the sample. Alternatively, the RF coil 128 may represent a single RF transmit/receive coil configured for implementing both transmitting and receiving functions. Alternatively, an RF transmit/receive coil may be provided in combination with one or more other RF transmit coils, with the different RF coils being tuned to different resonance frequencies as appreciated by persons skilled in the art. The RF coil(s) may have any suitable configuration, non-limiting examples of which include birdcage coils, saddle coils, Hemholtz coils, loop-gap resonators, slotted tube (e.g., Alderman-Grant style) resonators, scroll coils, etc. The NMR probe circuitry may include various electronics that provide an RF signal interface between the RF coil 128 and an external control/data acquisition system 134 of the NMR spectrometer 100, such as for resonant frequency tuning, impedance matching, filtering, NMR measurement signal amplification (i.e., a low noise preamplifier), etc., as appreciated by persons skilled in the art. For example, the NMR probe circuitry may include tune and match circuitry (located, for example, in a region 132 proximate to the RF coil 128), and a transmit/receive switch (T/R), a filter and, a receiver-side (pre-) amplifier (located, for example, in a region 138 at or near the base of the NMR probe 116).

Generally, the control/data acquisition system (or control/acquisition system) 134 is configured for controlling the RF transmit/receive operations, conditioning and processing the NMR measurement signals acquired from the sample, and producing frequency-domain NMR spectra therefrom. The control/acquisition system 134 may generally include RF transmitting circuitry (electronics) 136 and RF receiving circuitry (electronics) 140 communicating with the NMR probe circuitry, and a controller 144 (e.g., a computing device and associated hardware and software) communicating with the RF transmitting circuitry 136 and RF receiving circuitry 140. The RF transmitting circuitry 136 and RF receiving circuitry 140 selectively communicate with the RF coil 128 and other NMR probe circuitry via the T/R switch. The RF transmitting circuitry 136 is configured for generating RF energy and transmitting RF excitation signals to the RF coil 128 via the T/R switch and other NMR probe circuitry. For this purpose, the RF transmitting circuitry 136 may include a stable RF energy source (e.g., frequency synthesizer), a modulator for configuring the RF source signal according to desired parameters (e.g., amplitude, phase, shape, pulse width, etc.), a signal amplifier for scaling up the gated waveform (e.g., on the order of hundreds of watts), etc. The power level of the RF source signal may be frequency dependent. The phase shifting and pulse gating functions of the modulator may be controlled by a pulse programmer associated with the controller 144. The RF receiving circuitry 140 is configured for receiving, via the NMR probe circuitry and T/R switch, the NMR measurement signals detected by the RF coil 128 and processing the signals as needed to generate NMR spectra. For this purpose, the RF receiving circuitry 140 may include an RF receiver, an analog-to-digital converter (ADC), a phase shifter, a Fourier transform analyzer for converting the time-domain signal to a frequency-domain signal, etc. The RF receiving circuitry 140 may also include a low noise power supply for providing a DC bias to the LNA circuitry. The preamplifier provided by the NMR probe circuitry may be considered as the first stage of the RF receiving circuitry 140.

Generally, the controller 144 is configured for controlling the timing and operation of various components of the NMR spectrometer 100, such as the magnet 108, T/R switch, RF transmitting circuitry 136, and RF receiving circuitry 140. The controller 144 may include hardware (microprocessor, memory, etc.) and software components, as appreciated by persons skilled in the art. In FIG. 1 the controller 144 also schematically represents input and output devices that provide a user interface, including a readout or display device for presenting NMR spectra resulting from an experiment, as appreciated by persons skilled in the art.

In operation, before or after the NMR probe 116 is inserted into the bore 112, the sample holder 120 containing the sample to be irradiated is inserted in the NMR probe 116. The sample holder 120 is positioned such that the sample is coaxially surrounded by the RF coil 128 and immersed in the static B₀ field established by the magnet 108. RF excitation signals are transmitted from the RF transmitting circuitry 136 to the RF coil 128 according to a predefined pulse sequence, and the RF coil 128 applies corresponding periodic magnetic B₁ fields to the sample. In response, the sample emits NMR measurement signals that are processed by the RF receiving circuitry 140 to generate user-interpretable NMR spectra.

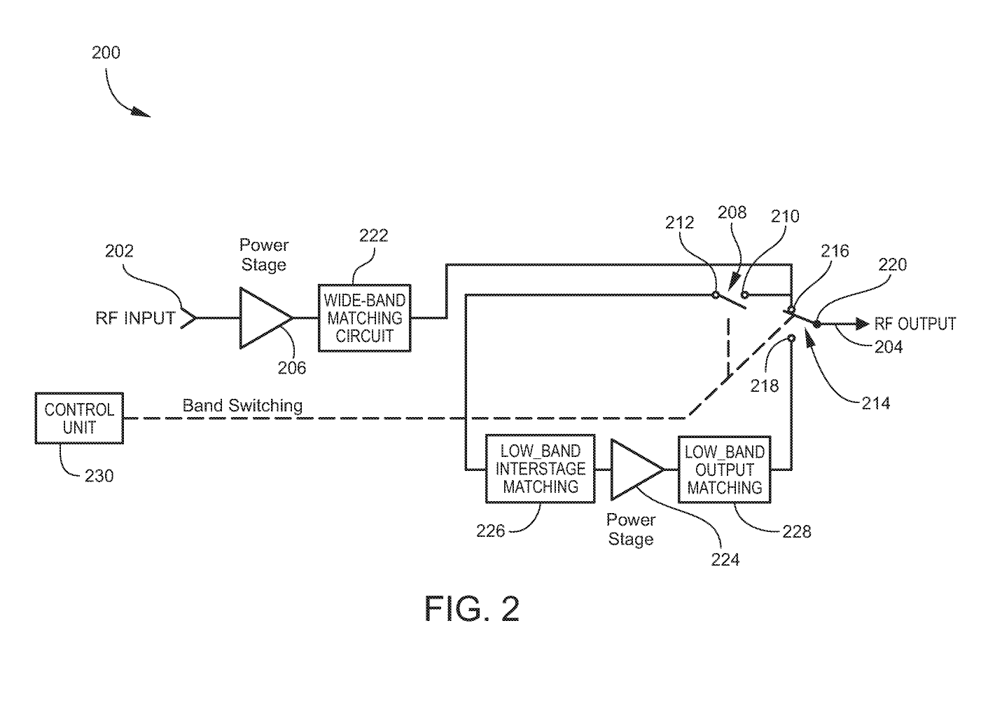

FIG. 2 is a block diagram of another example of a full-band power amplifier with a switched partial-band booster stage according to some embodiments. In the illustrated embodiment of FIG. 2, the RF transmitting circuitry 136 of FIG. 1 may include an RF power amplifier 200. The RF power amplifier 200 may include an RF signal input 202 and an RF signal output 204. The RF power amplifier 200 may be configured to receive an RF source signal via the RF signal input 202. The RF power amplifier 200 may be in electrical communication with the RF coil 128 of FIG. 1, as an example, providing for resonantly exciting high-frequency NMR-active nuclei and low-frequency NMR-active nuclei via the RF signal output 204.

In a first embodiment of a RF power amplifier, as illustrated in FIG. 2, the RF power amplifier 200 may include a first stage amplifier 206 configured to receive the RF source signal at the RF signal input 202. The first stage amplifier 206 may be configured to amplify the RF source signal to a first power level and/or over a wide frequency range as similarly described in FIG. 1. The RF power amplifier 200 may include a switch assembly. In the illustrated embodiment, the switch assembly includes a first switch 208 and a second switch 214. The first switch 208 includes a switch input 210 and a switch output 212. The second switch 214 includes a first switch input 216, a second switch input 218, and a switch output 220. The switches 208, 214 may be constructed with, for example, p-type-intrinsic-n-type (PIN) diode based switches. The switches 208, 214 may also be mechanical relays or other switch devices that may be similarly configured.

With continued reference to FIG. 2, a wide-band matching circuit 222 may be in electrical communication between the first stage amplifier 206 and the switch input 210 of the first switch 208 and the first switch input 216 of the second switch 214. The wide-band matching circuit 222 provides impedance matching over a wide frequency range as defined herein. The wide frequency range may range from 38 MHz to 603 MHz. Other wide frequency ranges may be used, such as 5 MHz to 1000 MHz. The wide-band matching circuit 222 provides for impedance matching between the first stage amplifier 206 and the first and second switches 208, 214. When the second switch 214 is controlled to output the RF signal received at the first switch input 216 of the second switch 214, the wide-band matching circuit 222 may be configured to output the amplified RF source signal as a first RF output signal over the wide frequency range at the RF signal output. The wide frequency range may comprise frequencies effective for resonantly exciting high-frequency NMR-active nuclei and low-frequency NMR-active nuclei. As more specific yet non-limiting examples, the first power level may range from 20 W to 200 W and the wide frequency range may range from 38 MHz to 603 MHz.

With continued reference to FIG. 2, the RF power amplifier 200 may include a second stage amplifier 224 in electrical communication between the switch output 212 of the first switch 208 and the second switch input 218 of the second switch 214. The second stage amplifier 224 may be configured to receive the amplified RF source from the wide-band matching circuit 222 via the first switch 208. Thus, the wide-band amplifier circuitry becomes the exciter or driver for the second stage amplifier 224. When the second switch 214 is controlled to output RF signal received at the second switch input 218 of the second switch 214, the second stage amplifier 224 may provide the output of the amplified RF source signal as a second RF output signal at a second power level at the RF signal output 204. The second power level may be higher than the first power level, and also at a lower frequency range. As an example, the low frequency range may range from 38 MHz to 248 MHz and at a power level of substantially equal to 350 W. In alternative embodiments, the low frequency range may extend from 5 MHz to 500 MHz at a power level of 250 W to 400 W. The low frequency range may include frequencies effective to resonantly excite deuterium (H-2), carbon (e.g., carbon-13), nitrogen (e.g., nitrogen-15), potassium (³⁹K), and phosphorous (e.g., phosphorous-31) nuclei, as an example. The RF power amplifier 200 may also include a low-band interstage matching circuit 226 for impedance matching between the switch output 212 of the first switch 208 and the second stage amplifier 224. The RF power amplifier 200 may also include a low-band output matching circuit 228 for impedance matching between the second stage amplifier 224 and the second switch input 218 of the second switch 214.

With continued reference to FIG. 2, the RF power amplifier 200 may include a control unit 230 to selectively control the first switch 208 and the second switch 214. The control unit 230 may be controlled by the controller 144 of FIG. 1. The control unit 230 may be or include a field-programmable gate array (FPGA), as an example.

With continued reference to FIG. 2, the switches 208, 214 may be physically co-located, such that the signal path length between the switch input 210 of the first switch 208 and the first switch input 216 of the second switch 214 (i.e., the physical transmission pathway length between the switch inputs 210, 216) is very short. It may be desirable for the transmission pathway between the switch inputs 210, 216 to be shorter than 1/10 wavelength at the highest operating frequency. This may be configured to avoid the formation of an open stub when the second switch 214 is set to the low-band position (i.e., coupled to the second switch input 218) and the first switch 208 is open.

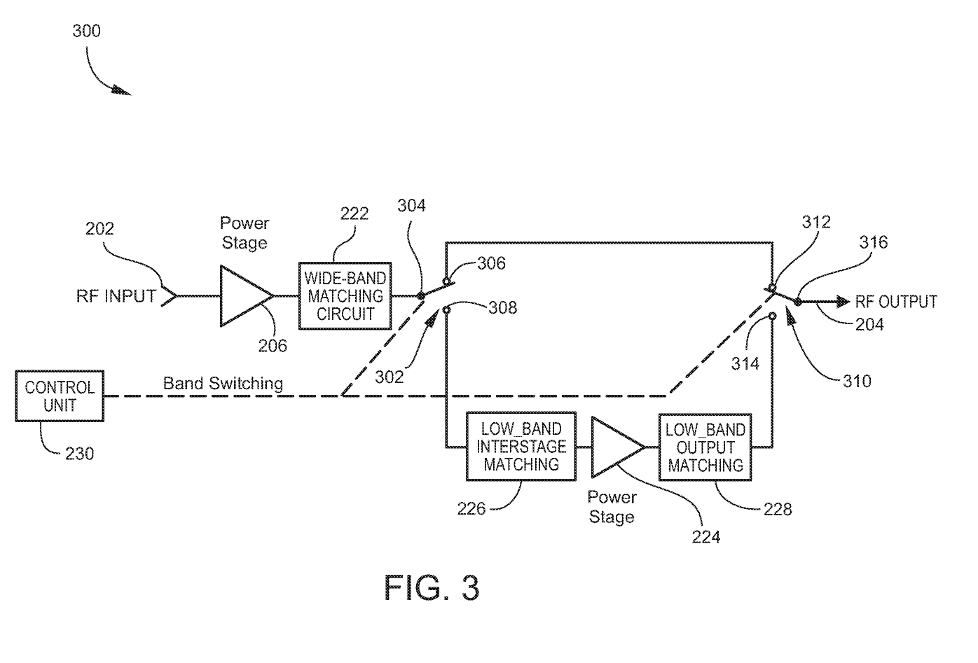

FIG. 3 is a block diagram of another example of a full-band power amplifier with a switched partial-band booster stage according to some embodiments. In the illustrated embodiment of FIG. 3, the RF transmitting circuitry 136 of FIG. 1 may include an RF power amplifier 300. The RF power amplifier 300 may include an RF signal input 202 and an RF signal output 204. The RF power amplifier 300 may be configured to receive an RF source signal via the RF signal input 202. The RF power amplifier 300 may be in electrical communication with the RF coil 128 of FIG. 1, as an example, providing for resonantly exciting high-frequency NMR-active nuclei and low-frequency NMR-active nuclei via an RF signal output 204.

In a second embodiment of a RF power amplifier, as illustrated in FIG. 3, the RF power amplifier 300 may include the first stage amplifier 206 configured to receive the RF source signal at the RF signal input 202. The first stage amplifier 206 may be configured to amplify the RF source signal to a first power level and/or over a wide frequency range as similarly described in FIG. 2. The RF power amplifier 300 may include a switch assembly. In the illustrated embodiment, the switch assembly includes a first switch 302 and a second switch 310. The first switch 302 includes a switch input 304, a first switch output 306 and a second switch output 308. The second switch 310 includes a first switch input 312, a second switch input 314, and a switch output 316. The switches 302, 310 may be constructed with, for example, p-type-intrinsic-n-type (PIN) diode based switches. The switches 302, 310 may also be mechanical relays or other switch devices that may be similarly configured.

With continued reference to FIG. 3, the wide-band matching circuit 222 may be in electrical communication between the first stage amplifier 206 and the switch input 304 of the first switch 302. The wide-band matching circuit 222 provides for impedance matching between the first stage amplifier 206 and the switch input 304. The RF power amplifier 300 may be configured to output the amplified RF source signal as a first RF output signal at a wide frequency range comprising frequencies effective for resonantly exciting high-frequency NMR-active nuclei and low-frequency NMR-active nuclei as similarly described above in conjunction with FIG. 2.

With continued reference to FIG. 3, the RF power amplifier 300 may include a second stage amplifier 224 in electrical communication between the second switch output 308 of the first switch 302 and the second switch input 314 of the second switch 310. The second stage amplifier 224 may be configured to receive the amplified RF source from the wide-band matching circuit 222 via the first switch 302. In this manner, the wide-band amplifier circuit 222, becomes the exciter or driver for the second stage amplifier 224. When the second switch 310 is controlled to output the RF signal received at the second switch input 314 of the second switch 310, the second stage amplifier 224 may provide the output of the amplified RF source signal as a second RF output signal at a second power level at the RF signal output 204. The second power level may be higher than the first power level, and also at a lower frequency range. As an example, the lower frequency range may include frequencies effective for resonantly exciting low-frequency NMR-active nuclei as similarly described in FIG. 2. The RF power amplifier 300 may also include the low-band interstage matching circuit 226 for impedance matching between the second switch output 308 of the first switch 302 and the second stage amplifier 224. The RF power amplifier 300 may also include the low-band output matching circuit 228 for impedance matching between the second stage amplifier 224 and the second switch input 314 of the second switch 310.

With continued reference to FIG. 3, the RF power amplifier 300 may include a control unit 230 to selectively control the first switch 302 and the second switch 310. The control unit 230 may be controlled by the controller 144 of FIG. 1. The control unit 230 may be or include a field-programmable gate array (FPGA), as an example.

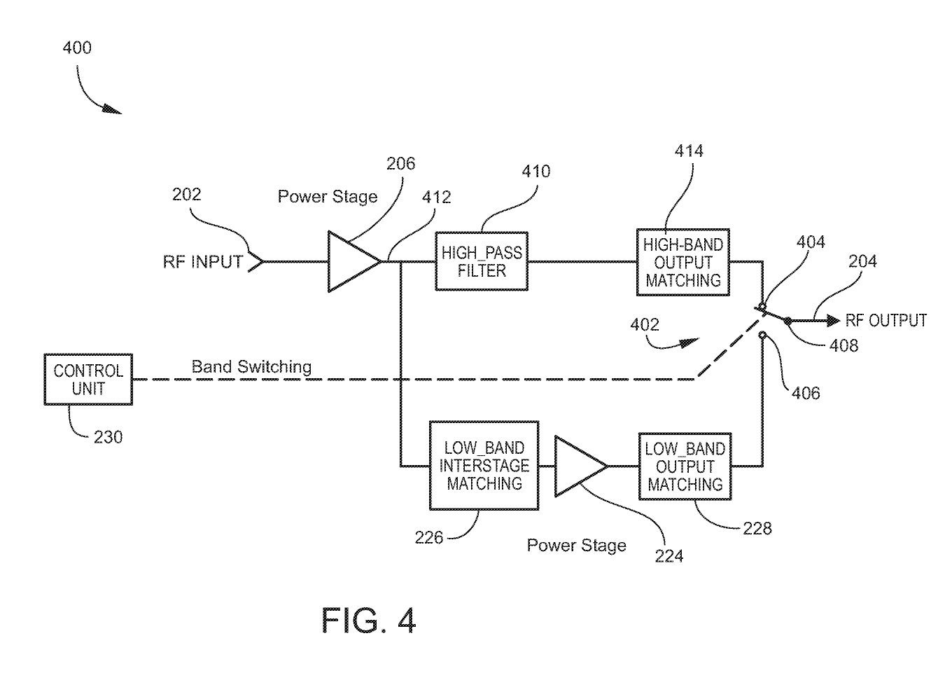

FIG. 4 is a block diagram of an example of a full-band power amplifier with a switched partial-band booster stage according to some embodiments. In the illustrated embodiment, the RF transmitting circuitry 136 of FIG. 1 may include an RF power amplifier 400. The RF power amplifier 400 may include the RF signal input 202 and the RF signal output 204. The RF power amplifier 400 may be configured to receive an RF source signal via the RF signal input 202. The RF power amplifier 400 may be in electrical communication with the RF coil 128 (via the NMR probe circuitry) providing, as an example, for resonantly exciting high-frequency NMR-active nuclei and low-frequency NMR-active nuclei via the RF signal output 204.

In a first embodiment, the RF power amplifier 400 may include the first stage amplifier 206 configured to receive the RF source signal. The first stage amplifier 206 may also be configured to amplify the RF source signal to a first power level and over a wide frequency range (or “full band”). As an example, the frequency range may include frequencies effective for resonantly exciting high-frequency, NMR-active nuclei and low-frequency, NMR-active nuclei in the NMR spectrometer 100. As more specific yet non-limiting examples, the first power level may range from 20 W to 200 W and the wide frequency range may range from 38 MHz to 603 MHz. In another example, the wide frequency range may include frequencies ranging from 5 MHz to 1000 MHz. The RF power amplifier 400 may also include a switch 402 including a first switch input 404, a second switch input 406, and a switch output 408. The switch output 408 may be in electrical communication with the NMR probe 116 via a suitable transmission line. The switch 402 may be configured to selectively output at the switch output 408 an input received at the first switch input 404 or an input to the second switch input 406. The switch 402 may be constructed with p-type-intrinsic-n-type (PIN) diode based switches. The switch 402 may also be constructed using mechanical relays or other switch devices that may be similarly configured.

The RF power amplifier 400 may also include a high-pass filter 410 in electrical communication between an output 412 of the first stage amplifier 206 and the first switch input 404. The high-pass filter 410 may be configured to receive the amplified RF source signal from the first stage amplifier 206. When the switch 402 is controlled to output the received amplified RF source signal input to the first switch input 404, the high-pass filter 410 may be further configured to output the amplified RF source signal as a first RF output signal. The first RF output signal may be at a high frequency range comprising, for example, frequencies effective for resonantly exciting high-frequency, NMR-active nuclei, as an example. As more specific yet non-limiting examples, the high frequency range of the first RF output signal may range from 300 MHz to 1000 MHz, and the power level of the first RF output signal may range from 50 W to 150 W. The high frequency range may include frequencies effective to resonantly excite hydrogen and fluorine nuclei, as an example. The high-pass filter 410 may also electrically communicate with a high-band output matching circuit 414 for impedance matching between the high-pass filter 410 and the switch 402.

With continued reference to FIG. 4, the RF power amplifier 400 may also include the second stage amplifier 224 which may be in electrical communication between the first stage amplifier 206 and the second switch input 406. The second stage amplifier 224 may be configured to receive the amplified RF source signal and configured to output the amplified RF source signal as a second RF output signal at a second power level. The second power level may be higher than the first power level, and may be at a low frequency range comprising, for example, frequencies effective for resonantly exciting low-frequency NMR-active nuclei. The second RF output signal may be output at the RF signal output 204 when the switch 402 is controlled to output the input (e.g., RF source signal received) to the second switch input 406. In this example, the low frequency range may range from 38 MHz to 248 MHz and at a power level of substantially equal to 350 W. In alternative embodiments, the low frequency range may extend from 5 MHz to 500 MHz at a power level of 250 W to 400 W. The low frequency range may include frequencies effective to resonantly excite deuterium (H-2), carbon (e.g., carbon-13), nitrogen (e.g., nitrogen-15), and phosphorous (e.g., phosphorous-31) nuclei, as an example. The RF power amplifier 400 may also include a low-band interstage matching circuit 226 for impedance matching between the first stage amplifier 206 and the second stage amplifier 224. The RF power amplifier 400 may also include a low-band output matching circuit 228 for impedance matching between the second stage amplifier 224 and the second switch input 406. Impedance matching, as is described herein, is the practice of designing the input impedance of an electrical load or the output impedance of its corresponding signal source to maximize the power transfer or minimize signal reflection from the load. The impedance of the output of the first stage amplifier 206 may differ from the input of the either the switches or subsequent load circuits (e.g., second stage amplifier, high-band or low-band matching circuits), though it may be desired to minimize the impedance mismatch between the two (2) respective loads. The impedance of the matching circuits described herein may be configured with either an input or output impedance of substantially equal to fifty (50) ohms, as an example.

With continued reference to FIG. 4, the RF power amplifier 400, may include a control unit 230 to selectively control the switch 402. The control unit 230 may be controlled by the controller 144 of FIG. 1. The control unit 230 may be or include a field-programmable gate array (FPGA), as an example.

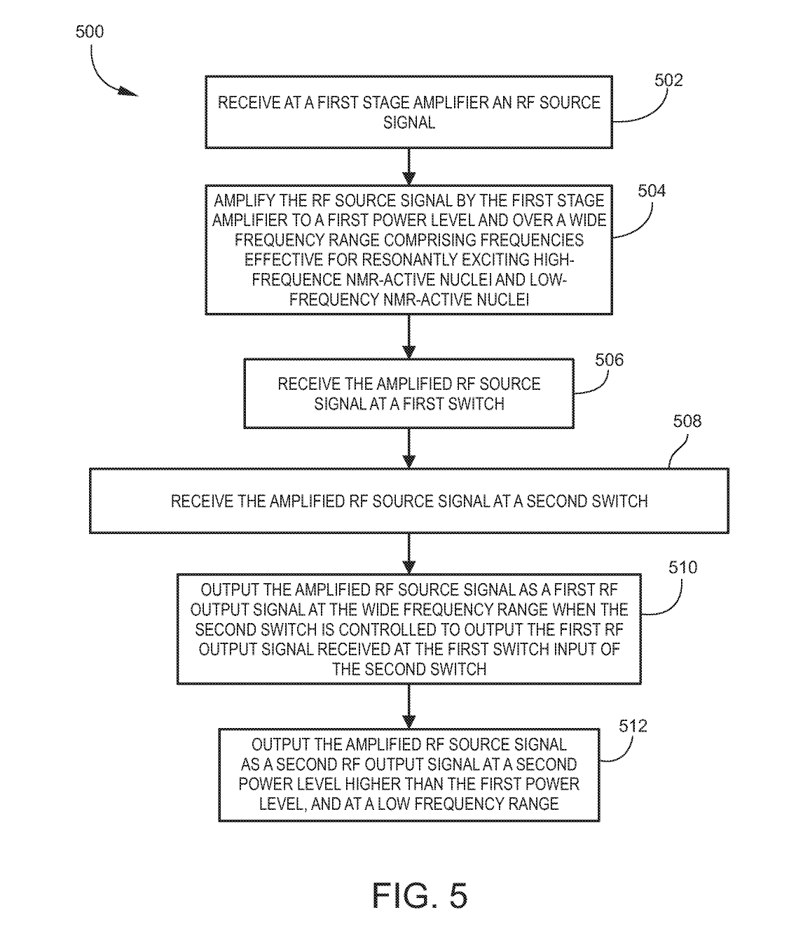

FIG. 5 is a flowchart of an example method 500 for full-band power amplification with a switched partial-band booster stage according to some embodiments. The method 500 may include receiving 502 at the first stage amplifier 206 an RF source signal. The first stage amplifier 206 may be configured for amplifying 504 the RF source signal to a first power level and over a wide frequency range comprising frequencies effective for resonantly exciting high-frequency NMR-active nuclei and low-frequency NMR-active nuclei, as described herein. The method 500 may also include providing the first switch 208 comprising the switch input 210 and the switch output 212 for receiving 506 the amplified RF source signal. The method 500 may also include providing the second switch 214 comprising the first switch input 216, the second switch input 218, and the switch output 220, also for receiving 508 the amplified RF source signal. The method 500 may also include using the wide-band matching circuit in electrical communication to match impedance between the first stage amplifier 206 and the switch input 210 of the first switch 208 and the first switch input 216 of the second switch 214. The wide-band matching circuit 222 may be configured for outputting 510 the amplified RF source signal as a first RF output signal at a wide frequency range comprising frequencies effective for resonantly exciting high-frequency NMR-active nuclei and low-frequency NMR-active nuclei when the second switch is controlled to output the RF signal received at the first switch input 216 of the second switch 214. The method 500 may also include using the second stage amplifier 224 in electrical communication to match impedance between the switch output 212 of the first switch 208 and the second switch input 218 of the second switch 214. The second stage amplifier 224 may be configured for receiving the amplified RF source and the second stage amplifier 224 may be configured for outputting 512 the amplified RF source signal as a second RF output signal at a second power level higher than the first power level. The second stage amplifier 224 may also output the amplified RF source signal at a low frequency range comprising frequencies effective for resonantly exciting low-frequency NMR-active nuclei when the second switch 214 is controlled to output the RF signal received at the second switch input 218 of the second switch 214.

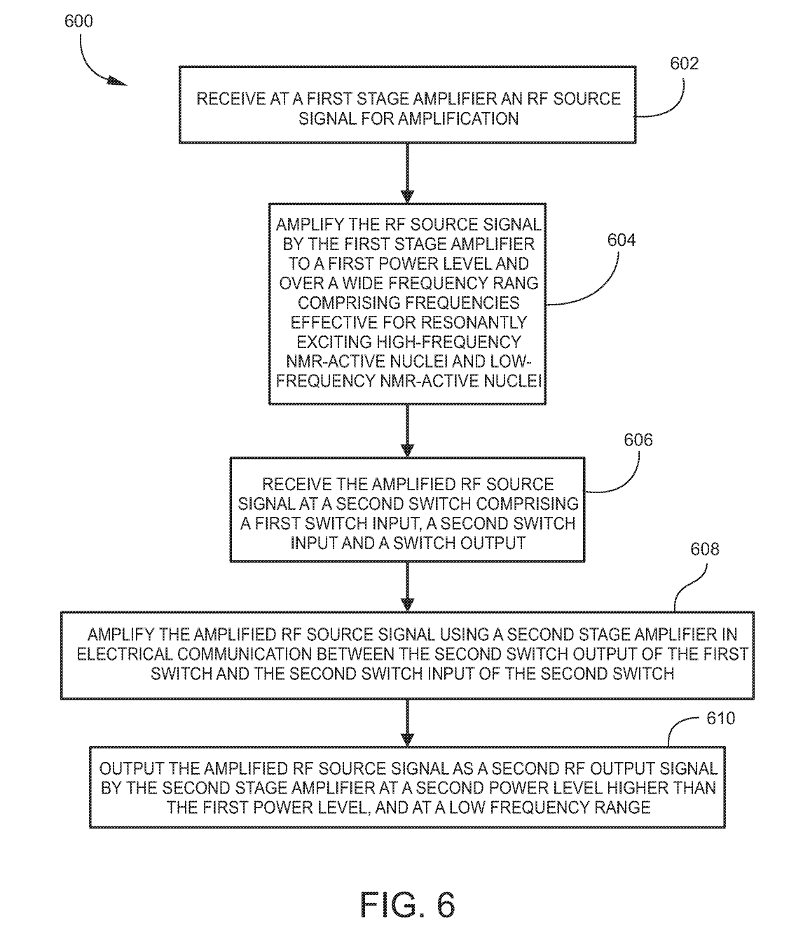

FIG. 6 is a flowchart of another example method 600 for full-band power amplification with a switched partial-band booster stage according to some embodiments. The method 600 may include receiving 602 at the first stage amplifier 206 an RF source signal. The first stage amplifier 206 may be configured for amplifying 604 the RF source signal to a first power level and over a wide frequency range comprising frequencies effective for resonantly exciting high-frequency NMR-active nuclei and low-frequency NMR-active nuclei, as described herein. The method 600 may also include providing the first switch 302 comprising the switch input 304, the first switch output 306, and the second switch output 308. The method 600 may also include providing the second switch 310 for receiving 606 the amplified RF source signal, the second switch may include the first switch input 312, the second switch input 314, and the switch output 316. The method 600 may also include using the wide-band matching circuit 222 in electrical communication between the first stage amplifier 206 and the switch input 304 of the first switch 302. The wide-band matching circuit 222 may be configured for outputting the amplified RF source signal as a first RF output signal at a wide frequency range comprising frequencies effective for resonantly exciting high-frequency NMR-active nuclei and low-frequency NMR-active nuclei. The method 600 may also include using the second stage amplifier 224 in electrical communication between the second switch output 308 of the first switch 302 and the second switch input 314 of the second switch 310 for amplifying 608 the amplified RF source signal. The second stage amplifier 224 may be configured for outputting 610 the amplified RF source signal as a second RF output signal at a second power level higher than the first power level. The second stage amplifier 224 may also be configured for outputting 610 the amplified RF source signal at a low frequency range comprising frequencies effective for resonantly exciting low-frequency NMR-active nuclei when the second switch 310 is controlled to output the RF signal received at the second switch input 314 of the second switch 310.

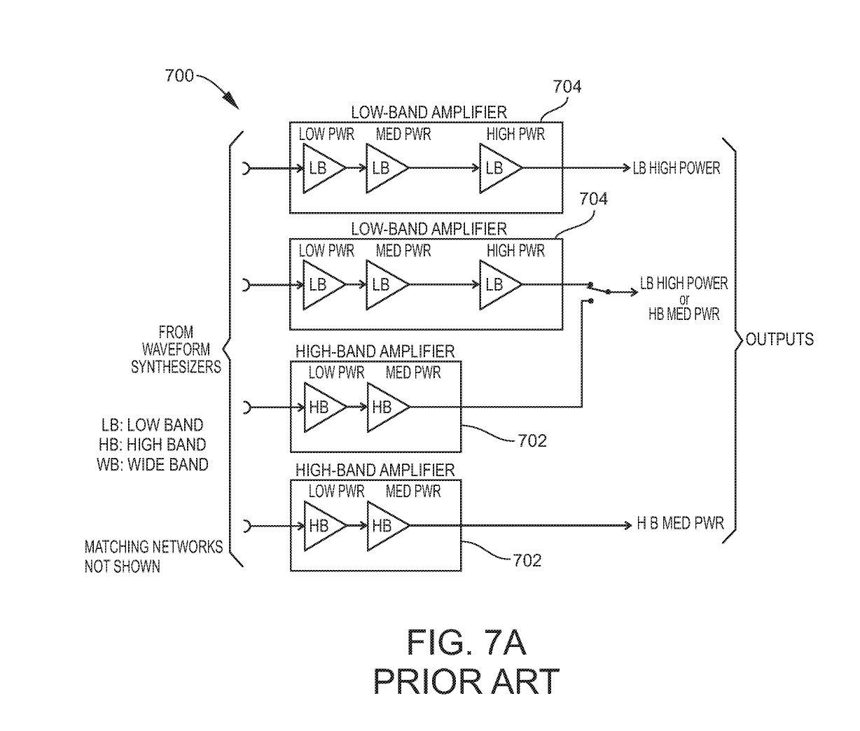

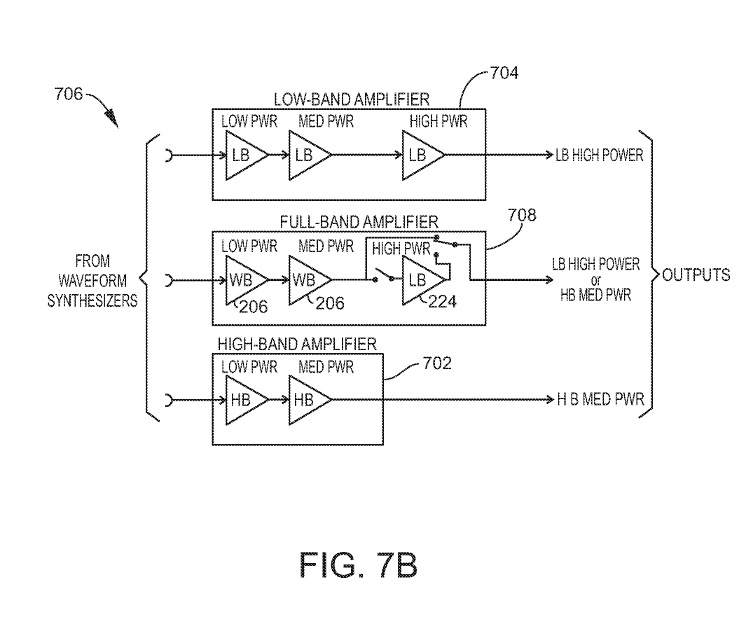

FIG. 7A is a block diagram of a prior art example for a typical RF power amplifier 700. The prior art example shows a RF power amplifier 700 configured using a selection of discrete high-band 702 and low-band 704 amplifiers, as necessary to cover all anticipated modes of operation. For example, if the anticipated modes of operation included H/H (simultaneous operation of two high-band amplifiers), H/L (simultaneous operation of a high-band and a low-band amplifier), and H/L/L, then the system would include four amplifiers, two high-band 702 and two low-band 704.

FIG. 7B is a block diagram of an example of a RF power amplifier 706 according to some embodiments disclosed herein. As an example, one (1) high-band 702 and one (1) low-band 704 amplifier may be replaced by a full-band amplifier 708 according to an embodiment disclosed herein. In FIG. 7B, the full-band amplifier 708 may include several low and medium power wide-band amplifiers, as an example. The low and medium power wide-band amplifiers may, as an example, be at least one first stage amplifier 206. As an example, medium power may be characterized as 20-100 watts, and high power may be characterized as 300-1000 watts. The full-band amplifier 708 may only cost a small amount more than a low-band amplifier to manufacture, thus the savings realized may be almost equal to the cost of a complete high-band amplifier 702. Additionally, the embodiments disclosed herein may be more compact and less power consuming than the typical RF power amplifier 700, as an example.

In other embodiments, the flow diagrams of FIGS. 5 and 6 may be representative of power amplifiers, or devices or systems including power amplifiers, configured for performing the steps or functions described above in conjunction with FIGS. 5 and 6.

The present subject matter has been described primarily in the context of an NMR spectrometer. It will be understood, however, that this context is given by way of example only as the present subject matter is applicable to other contexts or operating environments. For example, the NMR apparatus to which the present subject matter is applied may be configured as a (nuclear) magnetic resonance imaging (MRI) apparatus. Accordingly, the term “NMR apparatus” encompasses an NMR spectrometer and an MRI apparatus. More generally, the present subject matter may be applied to a variety of other RF transmitting devices that enable selection of different frequency ranges and levels of power amplification. As an example, the present subject matter may be applied to radar systems.

It will be understood that terms such as “communicate” and “in . . . communication with” (for example, a first component “communicates with” or “is in communication with” a second component) are used herein to indicate a structural, functional, mechanical, electrical, signal, optical, magnetic, electromagnetic, ionic or fluidic relationship between two or more components or elements. As such, the fact that one component is said to communicate with a second component is not intended to exclude the possibility that additional components may be present between, and/or operatively associated or engaged with, the first and second components.

It will be understood that various aspects or details of the invention may be changed without departing from the scope of the invention. Furthermore, the foregoing description is for the purpose of illustration only, and not for the purpose of limitation—the invention being defined by the claims.

What is claimed is:

1. A radio frequency (RF) power amplifier for amplifying a radio frequency (RF) source signal comprising:
a first stage amplifier configured to:
receive an RF source signal; and
amplify the RF source signal at the first stage amplifier to a first power level and over a wide frequency range comprising frequencies effective for resonantly exciting high-frequency nuclear magnetic resonance (NMR)-active nuclei and low-frequency NMR-active nuclei;
a first signal path configured to transmit the amplified RF source signal over the wide frequency range to a RF signal output; and
a second signal path configured to transmit the amplified RF source signal, wherein the second signal path comprises:
a second stage amplifier configured to:
receive the amplified RF source signal;
amplify the RF source signal a second power level higher than the first power level, and over a low frequency range comprising frequencies effective for resonantly exciting low-frequency NMR-active nuclei; and
transmit the amplified RF source signal over the low frequency range to the RF signal output; and
wherein the RF power amplifier is configured to selectively switch between transmitting the amplified RF source signal over the first signal path and the second signal path.

2. The RF power amplifier of claim 1, the RF power amplifier further comprises:
a switch assembly comprising a first switch and a second switch;
a wide-band matching circuit configured to match the impedance between the first stage amplifier and the switch assembly; and
wherein the first signal path further comprises:
the second switch configured to transmit the amplified RF source signal to the RF signal output; and
wherein the second signal path further comprises:
a low-band interstage matching circuit configured to match the impedance between the first switch and the second stage amplifier; and
a low-band output matching circuit configured to match the impedance between the second stage amplifier and the second switch.

3. The RF power amplifier of claim 1, the RF power amplifier further comprises:
a switch assembly comprising a first switch and a second switch;
a wide-band matching circuit configured to match the impedance between the first stage amplifier and the switch assembly; and
wherein the first signal path further comprises:
the first switch and the second switch configured to transmit the amplified RF source signal to the RF signal output; and
wherein the second signal path further comprises:
the first switch configured to transmit the amplified RF source signal;
a low-band interstage matching circuit configured to match the impedance between the first switch and the second stage amplifier;
a low-band output matching circuit configured to match the impedance between the second stage amplifier and the second switch; and
the second switch configured to transmit the amplified RF source signal over the low frequency range to the RF signal output.

4. The RF power amplifier of claim 1, wherein the first stage amplifier is configured to amplify the RF source signal over frequencies ranging from 5 MHz to 1000 MHz.

5. The RF power amplifier of claim 1, wherein the first stage amplifier is configured to amplify the RF source signal over frequencies effective for resonantly exciting hydrogen, fluorine, deuterium, carbon, nitrogen, potassium, and phosphorous nuclei.

6. The RF power amplifier of claim 1, further comprises a control unit configured to control switching between the first signal path and the second signal path.

7. The RF power amplifier of claim 6, wherein the control unit comprises a field-programmable gate array (FPGA).

8. The RF power amplifier of claim 1, wherein the first stage amplifier is configured to amplify the RF source signal to a range of 20 watts to 200 watts.

9. The RF power amplifier of claim 1, wherein the second stage amplifier is configured to amplify the amplified RF source signal to a range of 250 watts to 400 watts.

10. The RF power amplifier of claim 2, further comprising a transmission pathway between the inputs of the first switch and the second switch, wherein the transmission pathway is less than one-tenth ( 1/10) of the wavelength at the highest operating frequency of the amplified RF source signal.

11. A method for amplifying a radio frequency (RF) source signal, the method comprising:
receiving the RF source signal at a first stage amplifier;
amplifying the RF source signal at the first stage amplifier to a first power level and over a wide frequency range comprising frequencies effective for resonantly exciting high-frequency nuclear magnetic resonance (NMR)-active nuclei and low-frequency NMR-active nuclei;
switching selectively between transmitting the amplified RF source signal over a first signal path and a second signal path, wherein:
transmitting the amplified RF source signal over the first signal path comprises transmitting the amplified RF source signal over the wide frequency range to a RF signal output; and
transmitting the amplified RF source signal over the second signal path comprises:
receiving the amplified RF source signal at a second stage amplifier;
amplifying the RF source signal at the second stage amplifier to a second power level higher than the first power level, and over a low frequency range comprising frequencies effective for resonantly exciting low-frequency NMR-active nuclei; and
transmitting the amplified RF source signal over the low frequency range to the RF signal output.

12. The method of claim 11, the method further comprising:
matching the impedance between the first stage amplifier and a switch assembly using a wide-band matching circuit, the switch assembly comprising a first switch and a second switch;
transmitting the amplified RF source signal over the first signal path further comprises:
transmitting the amplified RF source signal to the RF signal output via the second switch; and
transmitting the amplified RF source signal over the second signal path further comprises:
matching the impedance between the first switch and the second stage amplifier using a low-band interstage matching circuit; and
matching the impedance between the second stage amplifier and the second switch using a low-band output matching circuit.

13. The method of claim 11, the method further comprising:
matching the impedance between the first stage amplifier and a switch assembly using a wide-band matching circuit, the switch assembly comprising a first switch and a second switch;
transmitting the amplified RF source signal over the first signal path further comprises:
transmitting the amplified RF source signal to the RF signal output via the first switch and the second switch; and
transmitting the amplified RF source signal over the second signal path further comprises:
transmitting the amplified RF source signal via the first switch;
matching the impedance between the first switch and the second stage amplifier using a low-band interstage matching circuit;
matching the impedance between the second stage amplifier and the second switch using a low-band output matching circuit; and
transmitting the amplified RF source signal over the low frequency range to the RF signal output via the second switch.

14. The method of claim 11, wherein amplifying the RF source signal to the first power level and over the wide frequency range comprises amplifying the RF source signal over frequencies ranging from 5 MHz to 1000 MHz.

15. The method of claim 11, wherein amplifying the RF source signal to the first power level and over the wide frequency range comprises amplifying the RF source signal over frequencies effective for resonantly exciting hydrogen, fluorine, deuterium, carbon, nitrogen, potassium, and phosphorous nuclei.

16. The method of claim 11, further comprising providing a control unit to control switching between the first signal path and the second signal path.

17. The method of claim 16, wherein the control unit comprises a field-programmable gate array (FPGA).

18. The method of claim 11, wherein amplifying the RF source signal to the first power level comprises amplifying the RF source signal to a range of 20 watts to 200 watts.

19. The method of claim 11, wherein amplifying the amplified RF source signal comprises amplifying the amplified RF source signal to a range of 250 watts to 400 watts.

20. The method of claim 12, wherein transmitting the amplified RF source signal over the second signal path comprises transmitting the amplified RF source signal over a transmission pathway between the inputs of the first switch and the second switch, wherein the transmission pathway is less than one-tenth ( 1/10) of the wavelength at the highest operating frequency of the amplified RF source signal.
